(19) United States
(12) Patent Application Publication
(10) Pub. No.: US 2026/0250881 A1
(43) Pub. Date: Aug. 27, 2026

(54) DEVICES AND METHODS INVOLVING LOW-TEMPERATURE-GROWN DIAMOND IN ELECTRONIC DEVICES

(71) Applicant: The Board of Trustees of the Leland Stanford Junior University, Stanford, CA (US)

(72) Inventors: Srabanti Chowdhury, San Ramon, CA (US); Mohamadali Malakoutian, Stanford, CA (US)

(21) Appl. No.: 18/992,402

(22) PCT Filed: Jul. 14, 2023
(86) PCT No.: PCT/US2023/027787

§ 371 Date: Jan. 8, 2025

Related U.S. Application Data
(60) Provisional application No. 63/389,179, filed on Jul. 14, 2022.

(51) Int. Cl. C30B 29/04; C30B 28/14; H10W 40/25

(52) U.S. Cl. CPC C30B 29/04; C30B 28/14; H10W 40/254

(57) ABSTRACT

In exemplary methods, diamond is grown al low-temperature (e g., under 600° C. or under 400° C.) is grown. In one aspect, the method includes controlling growth of the diamond, during the diamond growth, by a gas chemistry that abates sp² carbon formation and enhances diamond grain sizes in both lateral and vertical directions in the diamond while mitigating new diamond grains from forming on top of each other. As another aspect, the low-temperature diamond is grown on a wafer including one or more Si-based semiconductor devices adjacent and sufficiently close to a hot spot in a channel region of the semiconductor device(s) to cause, during operation of the semiconductor device(s), heat to be drawn from multiple sides of the hot spot, without undermining performance during operation of the semiconductor device(s).

### BACKGROUND

Aspects of various embodiments are directed to semiconductor materials and devices, and their manufacture and uses, wherein the semiconductor materials include diamond for transporting heat.

In exemplary contexts, aspects of the present disclosure are directed to semiconductors with self-heating portions of circuitry, such as channel regions of active devices (e.g., field-effect transistor), and implementing diamond as part of the semiconductor device in a way to effectively remove heat from the self-heating portions. For example, at high powers, excessive heat is often generated in semiconductor-device channels and this heat tends to increase the carrier scattering which in turn results in lower mobility. Also, during operation of optical-type semiconductor devices, heat generated in such devices can cause a shift in the wavelengths of the light being processed by the devices.

Moreover, for semiconductor devices which are designed to operate at high frequencies, due to the scaling, heat dissipation from the semiconductor channel is more challenging. Oftentimes, operating the semiconductor devices at high frequencies causes one or more high-temperature peaks. As one of various types of application-specific examples, such a heat removal technique may be used with diamond grown on high frequency high power GaN-type transistors such as those used in power amplifiers. Consider, GaN power amplifiers (PAS) which are sometime used as high-frequency high-power (HFHP)) transistor-based amplifiers. These types of PAs have become the preferred solution for base stations for 5G cellular communications, and also airborne and naval RADAR applications. These applications along with Terrestrial hub communications and Terrestrial backhaul communications with high power output (Pout)/element can generate severe levels of heat which creates significant challenges to the architecture and design.

As high levels of heat during manufacturing of such semiconductors can degrade device performance and its lifetime (especially for high-power and high-frequency applications), in many applications it is important to grow the diamond at temperature levels within the tolerance levels of the semiconductor materials and circuits. High levels of heat during use of such semiconductors can also undermine semiconductors. This is particularly true for low-budget semiconductor devices such as those based on silicon materials (e.g., SiO₂ and SiN), wherein exposing a silicon based wafer to heat levels of more than about 500-600° C. can begin to damage aspects of such silicon-based active devices such as SiO₂ and various SiN type field-effect transistors (“FET”), for example, by adversely affecting their dopant mobility and possibly causing other problems such as causing metallic contacts to reflow, changing contact resistances, and degrading saturation currents of the FETs. See, e.g., S. Sedky, A. Witvrouw, H. Bender and K. Baert, “Experimental determination of the maximum post-process annealing temperature for standard CMOS wafers,” in IEEE Transactions on Electron Devices, vol. 48, no. 2, pp. 377-385, February 2001, doi: 10.1109/16.902741. For the above and other background aspects, see also the references cited in the U.S. Provisional upon which this patent document is based.

These and other matters have presented challenges to efficient operation of semiconductor devices as used in a variety of applications.

### SUMMARY OF VARIOUS ASPECTS AND EXAMPLES

Various examples/embodiments presented by the present disclosure are directed to issues such as those addressed above and/or others which may become apparent from the following disclosure. For example, some of these disclosed aspects are directed to methods and devices that use, or leverage from, low-temperature diamond growth.

In exemplary methods according to the present disclosure, diamond is grown at low-temperature (e.g., under 600° C.). In one aspect, the method includes controlling growth of the diamond, during the diamond growth, by a gas chemistry that abates sp² carbon formation and enhances diamond grain sizes in both lateral and vertical directions in the diamond while mitigating new diamond grains from forming on top of each other. As another aspect, the low-temperature diamond is grown on a wafer including (e.g., conformal with surface(s) of) one or more Si-based semiconductor devices adjacent and sufficiently close to a hot spot in a channel region of the semiconductor device(s) to cause, during operation of the semiconductor device(s), heat to be drawn from multiple sides of the hot spot, without undermining performance during operation of the semiconductor device(s).

Also according to the present disclosure, other example embodiments are directed to apparatuses which include semiconductor device(s) and low-temperature-grown diamond, conforming to at least one surface of the semiconductor device(s), with the low-temperature-grown diamond being evident post-manufacture (and after formation of a diamond layer ensuing from the growth) having at least one of: a phase purity of greater than 90 percent, and diamond grains in the diamond layer being more isotropic than columnar, and active devices in the semiconductor device(s) are not damaged. Accordingly, such an apparatus includes: one or more active semiconductor devices having a channel region associated with a hot spot which manifests during operation of the one or more semiconductor devices; and diamond adjacent and sufficiently close to the channel region to, during the operation, draw heat from multiple sides of the hot spot.

In connection with certain experimental embodiments, the present disclosure is directed to address problems in connection with increased power densities in semiconductor devices for electronics applications such as those used in from dense computing applications to data communications including radio frequency platforms for 5G/6G networks. In such electronics applications, Joule heating and the resulting high temperature in the channels of the active devices (e.g., due to the increased power density) can result in performance degradation and premature failure. Integration of diamond near the device channel, where hot spots form through direct chemical vapor deposition techniques can spread the heat efficiently by increasing the heat transfer coefficient. Diamond mostly grown at high temperatures (700-1000° C.), limits the way of integrating it with many semiconductor technologies.

In specific examples according to the present disclosure, certain embodiments are directed to a device and/or method involving such low-temperature diamond located around (e.g., around multiple or adjacent sides of) the one or more semiconductor devices so as to provide three-dimensional mitigation of heat as the heat is generated from the one or more semiconductor devices while in operation. In another specific example according to the present disclosure, certain embodiments are directed to semiconductor devices, wherein one or more of the devices has a hot spot associated with a channel in the one or more semiconductor devices, and a portion of the low-temperature diamond is to be located significantly close to the hot spot.

In another example, the semiconductor device has a hot spot associated with a channel in the one or more semiconductor devices, the semiconductor device includes an adjacent layer and a diamond layer, the low-temperature diamond layer being thermally coupled to the adjacent layer, and a portion of the diamond is to be located significantly close to the hot spot such that while the semiconductor device is in operation, heat from the hot spot is spread to the diamond layer and from the diamond layer.

In yet another example, a diamond (e.g., as a layer) is used in the device so as to provide a thermal conductivity which is dependent on an average grain size associated with the low-temperature diamond, and wherein the thermal conductivity in the range of 100-2000 W/mK. For example, by locating the diamond around the device in more than two dimensions, channel thermal resistance is reduced, and this eventually lowers a high temperature peak in the channel and flattens the temperature profile associated with said at least one of the one or more semiconductor devices.

In a method of manufacturing or treating a semiconductor device (e.g., associated with one of the above semiconductor devices), the low-temperature diamond or low-temperature diamond layer is added after a remaining portion of the semiconductor device is otherwise fabricated (e.g., ready to be tested). This may be realized, for example, by chemical vapor deposition of polycrystalline diamond and/or by a single (adding of the diamond) step.

In another example, a semiconductor device (e.g., associated with one of the above semiconductor devices) is characterized as operating at high switching speeds wherein such speeds are at least partially attributable to utilization of a technology (e.g., SiO, SiN, GaN, Ga₂O₃, InP) used in the semiconductor device and causing a hot spot in the semiconductor device to generate heat with the heat transported through paths or portions of the low-temperature diamond.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure except where noted to the contrary, and in which:

FIG. 1 is a plan-view SEM micrographs and Raman spectra of diamonds grown at different temperatures in only H₂/CH₄ gas environment, with the illustrations showing diamond structural quality and phase purity being degraded by reducing temperature, for purposes of explaining exemplary aspects of the present disclosure;

FIG. 2A is an illustration showing oxygen plasma impact on carbon bonding by etching sp² carbon double bonds, according to aspects of the present disclosure, and showing that the more reactive nature of sp² double bonds over sp³ single bonds results in sp² carbon bonds being preferentially etched by atomic oxygen;

FIGS. 2B, 2C, 2D and 2E respectively show SEM micrographs of diamonds which were grown in connection with example experimental embodiments at about 400° C. with various nucleation and growth parameters, according to certain exemplary aspects of the present disclosure;

FIGS. 3A, 3B and 3C are Raman spectra and SEM micrographs of diamonds which were grown in connection with example experimental embodiments at about 400° C. with various nucleation and growth parameters, according to certain exemplary aspects of the present disclosure;

FIG. 4 is a graph showing diamond-nucleation optimization at a first step for a multiple step technique, also according to certain exemplary aspects of the present disclosure, with the optimum precursor (e.g., CH₄%) found by sweeping the CH₄%, and which is shown in the graph of having a reduced FWHM (full-width-half-maximum) down to 6.6 cm⁻¹;

FIGS. 5A and 5B are also according to certain exemplary aspects of the present disclosure, and more particularly FIG. 5A is a graph-based depiction showing normalized thermoreflectance signal as a function of time (with inset image in FIG. 5A) and with lines that represent the experimental value and dots represent an analytical model fitted to the experimental values, and FIG. 5B depicts an EELS (electron energy loss spectroscopy) analysis at the diamond-SiO₂ interface showing chemical bonding type at various points;

FIGS. 6A and 6B, also being in accordance with examples of the present disclosure, are respectively: plan-view and cross-sectional view SEM micrographs of diamonds grown at 400° C. on Si₃N₄ as in FIG. 6A, and EDS results of PC diamond grown on Si₃N₄, as in FIG. 6B;

FIG. 7 is a set of images comparing more-conventional diamond grains having columnar structures with diamond grains having isotropic structures, with the diamond grains being grown (image on right) in accordance with an experimental semiconductor device of the present disclosure;

FIG. 8 is a flow diagram showing device-first (diamond-growth after) type of processing of a 3D heat-spreading device in accordance with an experimental semiconductor device of the present disclosure; and

FIG. 9 is a set of depictions representing example aspects of gas chemistry used to realize various structures (via an exemplary diamond growth at about 400 degrees C.) discussed in connection with certain of the above-referenced illustrations, also according to the present disclosure.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving devices characterized in certain exemplary embodiments at least in part by low-temperature grown diamond wherein the low temperature is in a range of less than 600° C. to slightly below 400° C., and a gas chemistry for growing the diamond (e.g., including an amount or a selected percentage of O₂ or CO₂) abates sp² carbon formation and enhances diamond grain sizes in both lateral and vertical directions in the diamond layer while mitigating new diamond grains from forming on top of each other. Also, it may be appreciated that the following discussion in certain instances refers to polycrystalline diamond in connection with low-temperature-grown diamond layers, such discussion is for providing merely an exemplary context to help explain such aspects. The present disclosure is not necessarily limited to these and other such aspects. An understanding of specific examples in the following description may be understood from discussion in such specific contexts as further presented herein below.

In exemplary methods according to the present disclosure, diamond is grown at low-temperature (e.g., under 600° C.). In one aspect, the method includes controlling growth of the diamond, during the diamond growth, by a gas chemistry that abates sp² carbon formation and enhances diamond grain sizes in both lateral and vertical directions in the diamond while mitigating new diamond grains from forming on top of each other. As another aspect, the low-temperature diamond is grown on a wafer including (e.g., conformal with surface(s) of) one or more Si-based semiconductor devices adjacent and sufficiently close to a hot spot in a channel region of the semiconductor device(s) to cause, during operation of the semiconductor device(s), heat to be drawn from multiple sides of the hot spot, without undermining performance during operation of the semiconductor device(s).

Also according to the present disclosure, other example embodiments are directed to apparatuses which include semiconductor device(s) and low-temperature-grown diamond, conforming to at least one surface of the semiconductor device(s), with the low-temperature-grown diamond being evident post-manufacture (and after formation of a diamond layer ensuing from the growth) and having at least one of: a phase purity of greater than 90 percent, and diamond grains in the diamond layer being more isotropic than columnar, and active devices in the semiconductor device(s) are not damaged. Accordingly, such an apparatus includes: one or more active semiconductor devices having a channel region associated with a hot spot which manifests during operation of the one or more semiconductor devices; and diamond adjacent and sufficiently close to the channel region to, during the operation, draw heat from multiple sides of the hot spot.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Further specific examples of the present disclosure are directed to implementations for growing diamond under low temperature and using the diamond to aid in extracting heat from semiconductor and related devices for reducing channel temperature. Previous efforts by commonly-named inventors of the present disclosure have demonstrated polycrystalline (PC) diamond on GaN with grains larger than 2 μm as offering a thermal conductivity (TC)>650 W/m/K, which is larger than that of Si, SiC, GaN, and most any dielectric material's TC. Such high-quality diamond grains can be used as a heat spreading layer if it is integrated close to the hot spot. Because diamond has sp³ hybridized carbon atoms that attach to four other carbon atoms located at the vertices of a tetrahedron that makes a continuous and uniform 3D network of C—C sigma bonds, diamond can provide superior cross-plane TC to 2D materials and this 3D periodicity and large Debye temperature make diamond a superior heat conductor compared to other (2D) materials, semiconductors, and even metals when heat conduction in all directions is desired. In certain example implementations involving efforts to maximize the thermal management capabilities of PC diamond in 3D, an isotropic poly-grained layer with similar in-plane and cross-plane TCs is used. Isotropic PC diamond grains lessen the need for thick diamond layers for higher TC (unlike conventional diamond grown at temperatures of at least 650° C.), and diamond grown according to certain examples of the present disclosure lowers the thermal residual stress in the diamond layer after the growth.

In certain of the more-specific example embodiments, low temperature diamond is integrated at one or more of different stages of CMOS processing (such as back-end-of-line (BEoL)) which is only compatible with temperatures below 450° C., and for such BEOL-related examples, according to the present disclosure, low-temperature grown diamond is grown at temperatures corresponding to and compatible with such temperatures below 450° C., and in use with such lowered temperature to less than 600° C. during diamond growth, aspects of the present disclosure are used to mitigate higher sp² carbon incorporation which permits for increased sp³ (diamond) phase purity and to mitigate deterioration of thermal properties (e.g. TC) of the diamond layer. In such specific examples, the gas chemistry uses oxygen species (e.g., O₂) being introduced to the diamond-growth chamber and optimized to enhance sp² etching at lower temperatures and to promote sp³ formation. The added oxygen during low temperature growth takes the role of high temperature H₂-plasma during high temperature diamond growth by increasing the dissociation rate of methane monomers and diamond nucleation and accelerating the non-diamond etching rate. In contrast to previous studies on low temperature grown diamonds to date, specific example implementations consistent with the present disclosure not only reduce the growth temperature to well below <600° C. (e.g., <400° C.) but to also keep the thermal properties, phase purity, and anisotropy ratio similar to that of >600° C. grown diamond (diamond growth is typically at temperatures of 650-900° C.). In experimental examples of the present disclosure, such near-isotropic, low-temperature-grown diamond has been developed on SiO₂ and Si₃N₄ thin layers and can be integrated on all semiconductor-based devices with SiO₂ or Si₃N₄ dielectric capping.

The above types of low-temperature growth methods and apparatuses may involve any one or a combination of various examples (referring to examples, example embodiments and/or aspects) according to the present disclosure, and some of these examples are discussed below. One example is the low-temperature-growth diamond grown (grown well under 600° C.) being grown and/or formed on a Si-based material after formation of the one or more semiconductor devices having a uniform diamond layer that is characterized by at least one of: a phase purity of greater than 90 percent, and diamond grains in a uniform diamond layer being more isotropic than columnar, wherein Si-based active devices in the semiconductor devices are not damaged.

In other specific examples, one or more of the above methods involves specific exemplary aspects including one of more of the following aspects, such as the low-temperature-growth diamond being grown under different below 600° C. temperatures such as one or more temperatures below 500° C. and below 400° C. (e.g., not less than 200° C.), In connection with other aspects which may be used alone and/or with one or more aspects as above and/or hereinbelow: the diamond layer is uniform and the diamond grains are more isotropic than columnar, the chemistry includes an amount or a selected percentage of 02 and/or CO₂; the low temperature growth is achieved by modification of the plasma distance to the surface of the sample without changing the density of the plasma; the diamond-growth chemistry uses O₂, or CO₂ to etch sp² carbon and enhance the formation of sp³ carbon; the diamond growth includes an initial nucleation stage and after the initial nucleation stage, the diamond-growth chemistry is introduced to remove sp² carbon; the diamond-growth chemistry includes a selected percentage or amount of diamond growth precursors (e.g., H₂: 85-100%, CH₄: 0-10%, O₂: 0-6%, CO₂: 0-10%) to enhance or optimize the nucleation stage; and the diamond layer is grown with diamond grains configured to provide a degree of phase purity of not less than about 90%.

In yet further aspects according to the present disclosure (also useful as building on one or more of either above-characterized example embodiments and/or aspects), the selected percentage or amount of diamond growth precursor is selected by using a process that includes testing or sweeping for applying different percentages or amounts of the diamond growth precursors until an optimal percentage or amount of the CH₄, O₂, and CO₂ are found, and wherein the diamond layer is grown with diamond grains configured to provide optimal degrees of crystal quality and of phase purity similar to conventional high temperature diamonds.

Also in connection with exemplary apparatuses according to the present disclosure, the diamond layer may be characterized by at least one of: an anisotropy ratio (diamond thickness/grain size), in terms of thickness to grain size, of not greater than 1.76 and not less than 1.21; an average thermal conductivity of not less than 300 W/m/K; and a thermal boundary resistance as low as 5 m²K/GW.

In certain other exemplary apparatuses according to the present disclosure which may also build on the above-discussed aspects, semiconductor structures are directed to the following exemplary aspects. In one such example or aspect, the diamond is configured and arranged with: a first diamond layer adjacent the channel region and vertically separated from the substrate with at least a portion of the channel region located between the first diamond layer and the substrate layer; and a second diamond layer adjacent the channel region and elongated orthogonal to a plane along which at least a portion of the substrate is oriented, wherein during operation of the one or more semiconductor devices the first diamond layer is to draw heat away from the hot spot through the first diamond layer in a first spatial dimension, and the second diamond layer is to draw away heat from the hot spot through the first diamond layer in a second spatial dimension that is orthogonal to the first spatial dimension.

In other such aspects and/or examples: the semiconductor-based aspects include a third diamond layer adjacent the channel region and elongated orthogonal to the plane along which said at least a portion of the substrate is oriented, wherein in operation of the one or more semiconductor devices the third diamond layer is to draw away heat from the hot spot through the first diamond layer in a third spatial dimension that is orthogonal to the first and second spatial dimensions; the diamond is physically and thermally coupled to the substrate layer, and wherein the one or more semiconductor devices is at least partially manufactured; the diamond has a measure of thermal conductivity which is dependent on an average grain size associated with the diamond; the diamond is characterized as at least one of the following: a low-temperature grown diamond manifesting an additive of oxygen to a gas mixture by adding one or more (e.g., O₂ and/or CO₂) precursors; the low-temperature grown diamond and/or optimization of a nucleation stage during a growth stage or process of the low-temperature grown diamond is apparent from the diamond grains being more isotropic than columnar, the high degree of phase purity in the diamond, the diamond having a thermal conductivity in the range of 100-2000 W/mK, the diamond having a thermal conductivity which is dependent on an average grain size associated with the diamond, and/or the thermal conductivity of the diamond is in the range of 100-2000 W/mK.

The process(es) involving the optimized nucleation stage and/or the low-temperature grown diamond may also be apparent from the diamond and the channel region being configured to manifest a temperature profile in the channel and which temperature profile, during operation of the one or more semiconductor devices, is characterized by an eventual reduction of a peak temperature and a flattening of the temperatures profile. Also, such aspect(s) may be apparent from dissipation of heat from the hot spot through the diamond, at least one of the following properties: an anisotropy ratio less than 1.3 (e.g., in a range from 1.21 and 1.3); a low thermal boundary resistance not exceeding 5 m²k/GW; thermal conductivity of at least 300 W/mk; a minimized thermal boundary resistance (“TBR”, for example in a range from 5 to 15 m²K/GW”), and/or an enhanced thermal conductivity (“TC”, for example in a range of from 300±100 W/m/K).

Consistent with the above aspects, such a manufactured device or method of such manufacture may involve aspects presented and claimed in U.S. Provisional Application Ser. No. 63/389,179 filed on Jun. 14, 2022 (STFD.444P1 S22-301) with Addendums I and II and related Appendices (priority of the instant patent document being claimed to this U.S. Provisional application). To the extent permitted, such subject matter is incorporated by reference in its entirety generally and to the extent that further aspects and examples (such as experimental and/more-detailed embodiments) may be useful to supplement and/or clarify. Accordingly, for information regarding details of other embodiments, experiments and applications that can be combined in varying degrees with the teachings herein, reference may be made to this U.S. Provisional application, including its attachments, which form a part of this patent document and are fully incorporated herein by reference to the full extent permitted).

In connection with specific examples (including more-detailed/experimental examples) disclosed herein, examples of high-quality low-temperature diamond grown at any one or more of temperature(s) at or below less than 600° C. (e.g., less than 400° C., less than 475° C., less than 440° C., and/or less than 500° C.). The gas chemistry used with such growth may be selected and/or modified at different stages of the nucleation. In certain of these examples, this has involved or resulted in a small FWHM (full-width-half-maximum) sp³ Raman peak (~6.5 cm⁻¹, and referring to full-width-half-maximum) and high phase purity (e.g., greater than 90% and in some instances 97.1%), remarkably similar to >650° C. grown diamond (with >98% phase purity). With such more-detailed/experimental examples, the resulting diamond layers have included an average grain size of 650 nm with a thickness of 790 nm corresponding to an anisotropy ratio of 1.21 at 400° C. close to the best-reported anisotropy ratio of 1.12 for ~700° C. diamond. This near-isotropic diamond (i.e., anisotropy ratio of less than 1.3) exhibits a relatively high thermal conductivity of ~300 W/m/K and a thermal boundary resistance as small as only 5 m² K/GW (on SiO₂ and Si₃N₄ thin films), which can enhance the cooling efficiency of diamond for semiconductor devices including Si, InP, Ga₂O₃, and GaN technologies with SiO₂/Si₃N₄ capping/interfacial layers.

Certain examples of the present disclosure are directed to the low temperature growth of diamond on widely-used dielectrics in various semiconductor technologies such as Si, GaN, SiC, InP, and Ga₂O₃, with this diamond acting as a heat spreader and/or heat spreading solution for further applications. Reducing diamond growth temperature not only can expand the growth window for diamond on GaN-based devices but also enable the integration of diamond on other semiconductor devices, such as Silicon-based device, as a passivation layer or inter-layer dielectric. The use of only hydrogen plasma, typically used in diamond high temperature growth, during lower temperature growth is often found to be insufficient, for example, due to deteriorated diamond film quality due to a reduced etch rate of non-diamond carbons and an increased incorporation of sp² carbon. Here, the experimental efforts were used to develop a low temperature diamond growth technique at 400° C. by optimizing the gas mixture (H₂/CH₄/O₂), which produces diamond growth with similar quality, phase purity, and morphology to that of high-temperature grown diamond (e.g., at temperatures well above 600° C. such as 700° C.-grown diamond), and with the low temperature diamond growth realizing isotropic grains (even at 400° C.) with the lowest known anisotropy ratio of 1.21 (a value close to 1.12, which is the anisotropy ratio of previously 700° C. grown diamond as in other publications by named inventors common to the present patent document). The low anisotropy ratio provides a higher in-plane thermal conductivity as a plus to its significantly large crossplane thermal conductivity which is required for extra efficient device cooling in all directions. In such more-specific examples, measured average thermal conductivity is ~300 W/m/K and thermal boundary resistances are as low as 5 m²K/GW (which is remarkable relative to reported thermal material in their polycrystalline form).

Also according to the present disclosure, by using such manufacture-related methodology, various semiconductor structures and/or devices may be characterized as including some or all of the above-noted characteristics of the diamond layer(s) or grains of the diamond layer(s). As example, in devices produced from such processes, the process step of etching many sp² carbons (with more sp³ carbons) in connection with a nucleation stage of the low-temperature diamond growth as apparent from imaging in semiconductor devices (or products) produced from such processing involving gas chemistry to grow low-temperature diamond.

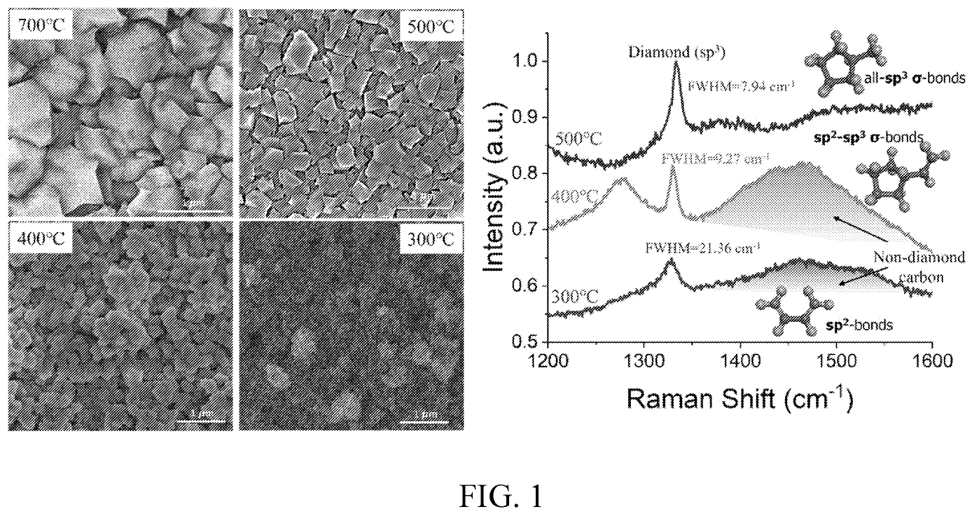

Turning now to the drawing, each of the above-noted figures pertains to more-detailed and/or experimental example embodiments in connection with certain surprising discoveries and realizations of the present disclosure. As noted above, FIG. 1 is a plan-view SEM micrographs and Raman spectra of diamonds grown at different temperatures in only H₂/CH₄ gas environment, with the illustrations showing diamond structural quality and phase purity being degraded by reducing temperature. In connection with these more-detailed and/or experimental example efforts, this includes growing diamond on SiO₂ and using a CH₄/H₂ gas system. It was determined that using only CH₄ and H₂ gases, which is typically used in standard high temperature (e.g., 700° C.) diamond growth, has limitations (e.g., relating to sp² carbons), and in contrast to such efforts involving such high temperature diamond growth, the structural properties of diamonds grown at 300° C. to 700° C. with CH₄/H₂ gases are assessed and compared. As shown in FIG. 1, by reducing the temperature, the grain shape, size, and crystallites change drastically. 700° C.-grown diamond shows the largest grains and 300° C.-grown diamond the smallest grains. In CH₄/H₂ gas system an activation energy of 20-30 kcal/mol is required for the abstraction of hydrogen atoms from C—H bonds at the surface to replace it with another carbon atom. At lower temperatures fulfilling this activation energy is challenging. Lower temperatures H₂-plasma is less efficient at etching sp² carbons and promoting sp³ formation over sp², thus the growth resulted in a soot-like carbon with significantly smaller grain sizes. This soot-like carbon layer was delaminated from the substrate easily due to the lack of strong adhesion and high residual stress. The 400° C.-grown diamond shows increased grain sizes and more facet-like diamond grains compared to 300° C. diamond due to the 100° C. increase in temperature. However, sp² carbon is still incorporated. Consequently, the re-nucleation rate is high which causes new diamond grains to form on top of each other instead of enlarging the existing grains. The crystal quality and phase purity were compared using Raman spectroscopy (as in FIG. 1). As a reference, the Raman spectra of a single crystalline diamond anvil cell was assessed to compare with polycrystalline samples. The Raman peak position and FWHM for the single crystalline diamond were measured as 1331.5 cm⁻¹ and 4.9 cm⁻¹, respectively. As expected, 700° C.-grown diamond exhibited higher crystalline quality (FWHM of sp³ peak ~5.7 cm^{-1]}) and higher phase purity (98%) compared to lower temperature grown polycrystalline diamonds. By decreasing the temperature, the FWHM increases (7.94 cm⁻¹ at 500° C., 9.27 cm⁻¹ at 400° C., 21.36 cm⁻¹ at 300° C.) and the phase purity deteriorates (94.9% at 500° C., 84.2% at 400° C., 75.4% at 300° C.) due to the incorporation of sp² carbon. As a result, a different gas system is necessary to grow high quality diamond at temperatures <500° C.

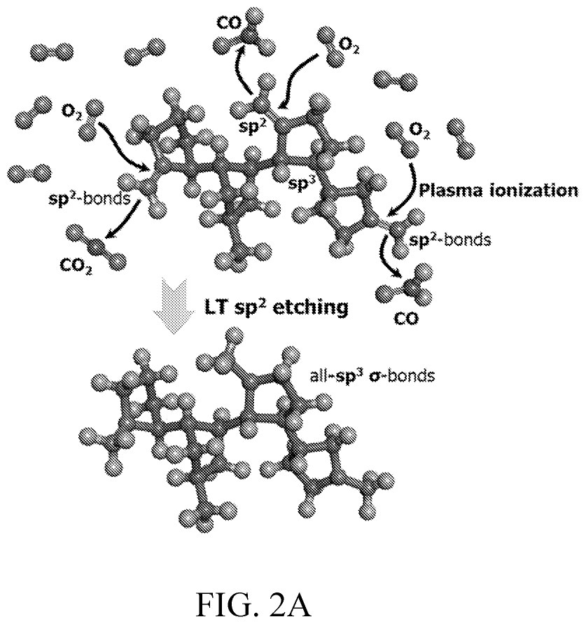

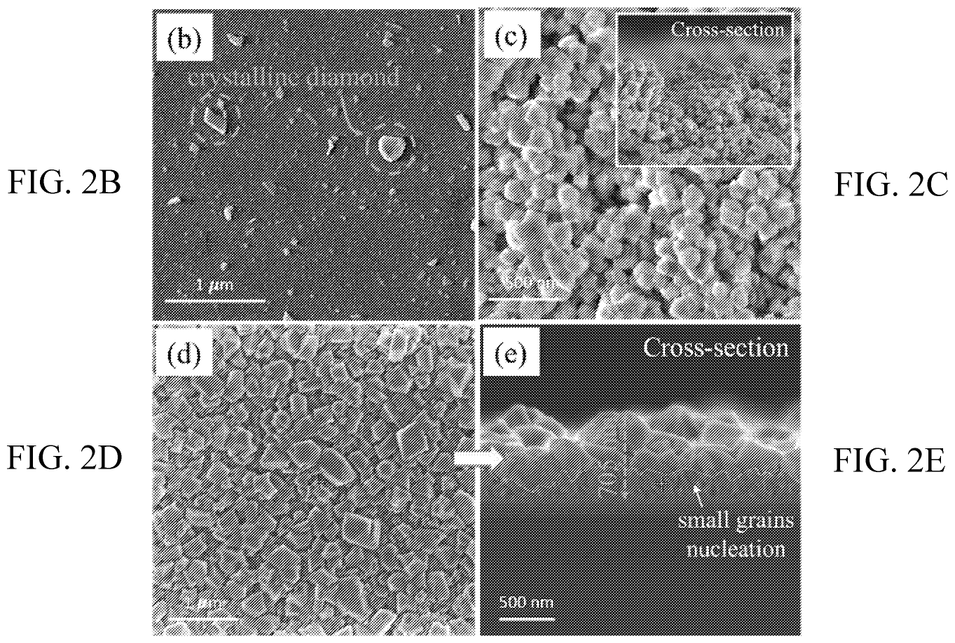

In connection with FIG. 2, specific example embodiments involved use of a modified gas system which involves the use of O₂/CH₄/H₂ gas for growth of the diamond according to aspects of the present disclosure.

The poor-quality diamond grown at low temperature using a CH₄/H₂ gas system described in the previous section motivated the study of a different gas chemistry that will not only enhance sp² (disordered) carbon etching but also lower the sp³ carbon growth activation energy. To enable a diamond growth at 400° C., that would show similar structural properties as the 700° C.-grown diamond, the addition of oxygen to the gas mixture and nucleation optimization were two necessary steps, described in this section. As shown in FIG. 2A, adding oxygen to the chamber etches carbon due to the high electronegativity of oxygen atoms. Oxygen preferentially attracts the electrons from the surface carbon-carbon bonds as carbon is not nearly as electronegative, hence breaking the carbon-to-carbon bonds. Between sp³ and sp² bonds, sp² carbon bonds are preferentially etched because while carbon-carbon double bonds are overall stronger, the individual bond energies of the two bonds are lower on average and so are more reactive than the carbon-carbon single bond, especially since the single bonds are mostly in rings which are extremely stable.

On sample #B₁ a 3.4% CH₄ and relatively high O₂ content (2%) was used for diamond growth. As shown in FIG. 2B, the grown layer is non-uniform with many diamond islands which did not coalesce. Higher etch rate of carbon due to the initiation of oxygen plasma and extremely low growth rate due to the insufficient atomic carbons (CH₃⁺) reduced the nucleation rate noticeably. The lack of appropriate diamond nucleation during the earlier stages of the growth resulted in the formation of sparse diamond particles. Even though, oxygen plasma enhances the dissociation process of carbon atoms from CH₄ for higher growth rate, it etches carbon-carbon bonds simultaneously. Furthermore, exposing the regions of SiO₂, uncovered by the diamond particles, to O₂-plasma even at lower temperatures increases the chance of roughening or etching of the surface which was observed in sample #B₁. For sample #B₂, a 1% O₂ and a 5% CH₄% were used as shown in FIG. 2C, higher re-nucleation rate than in sample #B₁ resulted in a uniform diamond coverage of the substrate but with much smaller grains. The inset cross-section SEM verifies high re-nucleation rate; however, ultra-nano-crystalline diamond (UNCD) growth was observed instead of desired micro-crystalline diamond (MCD) growth. To effectively nucleate and simultaneously decrease the re-nucleation rate to form larger grains, a combination of sample #B₁ and #B₂ growth parameters were used to achieve the results shown in FIG. 2D and FIG. 2E for sample #B₃. Using a relatively higher O₂ concentration right after the high re-nucleation stage makes the etching and growth comparable which reduces sp² carbon formation and at the same time minimizes the possibility of substrate damage (5-3% CH₄, 1-2% O₂).

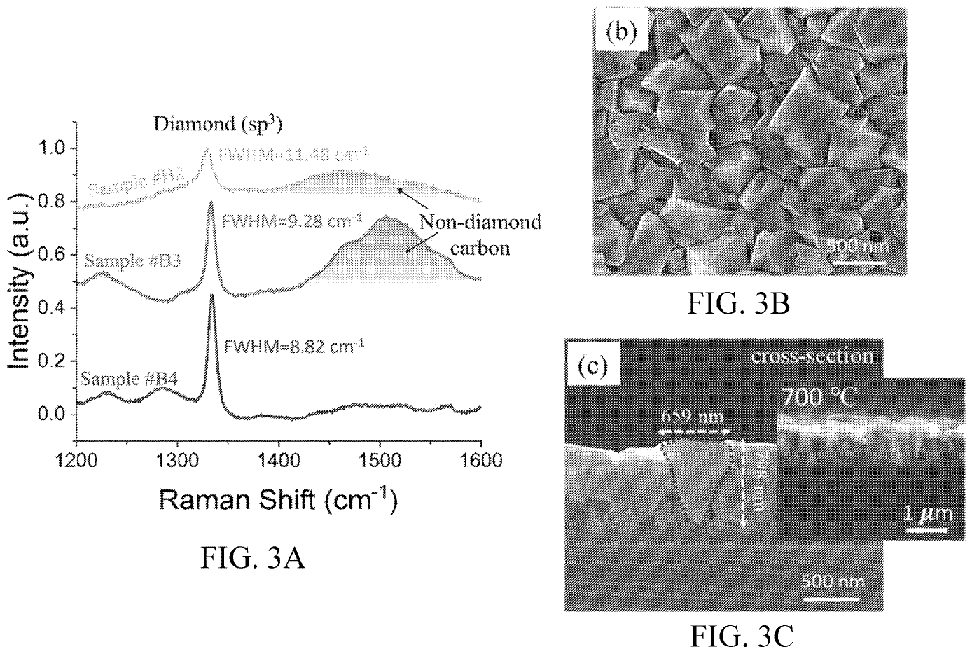

From these experimental efforts, it has been determined that when the lateral and vertical growth rate are comparable, isotropic grains of diamond is achievable. Isotropic grains provide higher effective TC, eliminating the need for thick diamond layers. The anisotropy ratio of the crystal grains for sample #B₃ was ~1.76 (705/400 nm) which is close to the ideal which is unity and which was substantially achieved in 700° C. growth. However, a thick nucleation layer with smaller grains (FIG. 2E) negatively affected the quality and phase purity of this layer which eventually can degrade its thermal properties. As extracted from Raman spectra in FIG. 3A, the FWHM of samples #B₂ and #B₃ were 11.5 and 9.3 cm⁻¹, respectively. This large FWHM along with high sp² incorporation lowers their phase purities to 83.6% and 92.5%. Thus, to increase phase purity, a 3-step growth technique was developed to simultaneously reduce sp² carbon and grow a uniform and completely coalesced layer (5% CH₄, 1.7% O₂→3.4% CH₄, 1.7% O₂→2.6% CH₄, 2% O₂). With this specific example technique, according to aspects of the present disclosure, not only was the sp² incorporation decreased (Sample #B₄ data in FIG. 3A), but also the small grain nucleation layer has disappeared, as shown in FIG. 3C. Additionally, the FWHM was reduced to 8.8 cm⁻¹, another sign of higher quality diamond than samples #B₂ and #B₃. For sample #B₄, the anisotropy ratio was dropped to 1.21, significantly closer to 1.12 for 700° C.-grown diamond (see inset of FIG. 3C).

Due to the mismatch in the coefficients of thermal expansion (CTE) between diamond and the substrate (GaN/SiC), a residual stress was present in the diamond layer. Since diamond's CTE (1.1×10⁻⁶ K⁻¹) is lower than the substrate, the stress after cooling from 400° C. deposition is compressive. In sample #B₂, a red shift of 2.6 cm⁻¹ from sp³ (diamond) peak position was measured, which is a sign of tensile stress in opposition to typical expectations due to a CTE mismatch. The main reason for this observation is the high re-nucleation rate which relaxes the diamond layer by UNCD formation. This layer as confirmed by SEM (FIG. 2C) has more grain boundaries and polyacetylene which eventually results in tensile stress by compensating the compressive stress caused by CTE mismatch. On the other hand, Samples #B₃ and #B₄ have a blue shift of 1.3 and 2.1 cm⁻¹, respectively. Since their thicknesses are in the same range, the higher compressive stress in sample #B₄ is due to the lower re-nucleation rate and sp² incorporation.

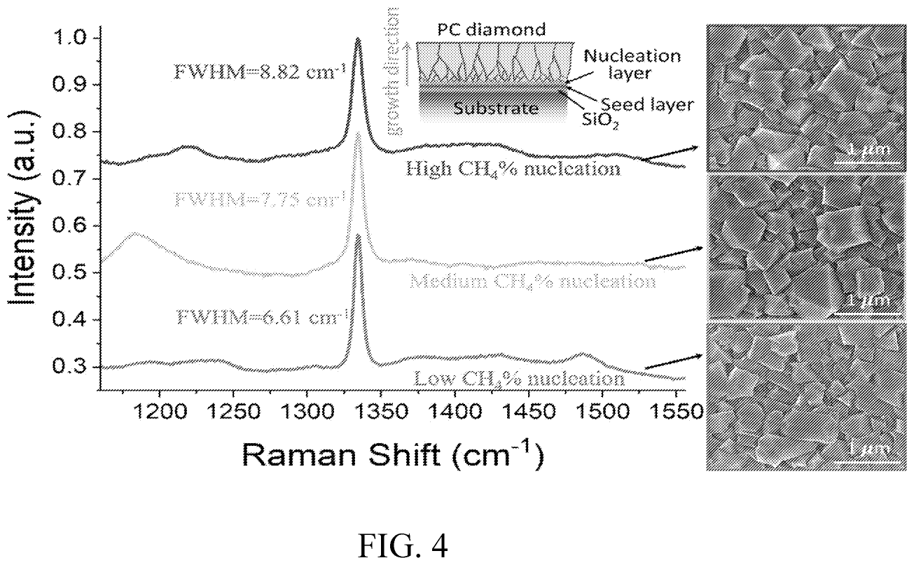

To reduce the FWHM, the diamond was grown at 400° C. (to make it closer to 700° C. diamond), and the experimental efforts were used to optimize the first step, the nucleation stage, by sweeping the CH₄%. As can be seen in the Raman spectroscopy results in FIG. 4, the lowest CH₄% (3.4%) during the first step nucleation that enables a uniform layer growth resulted in a narrower sp³ peak with a smaller 6.6 cm⁻¹ FWHM. While the top-view SEMs confirm no change in the grain size, grain shapes, and uniformity, lower CH₄% nucleation resulted in a narrower diamond peak and improved crystallinity.

Each of the results presented above (including FWHM, phase purity, Raman shift corresponding to residual stress, and anisotropy ratio) are summarized in Table 1 for purposes of comparison of results for different samples studied in connection with such specific experimental example embodiments of the present disclosure.

TABLE 1

| | Phase | | Raman | Residual | |
|---|---|---|---|---|---|
| | Purity^{α} | FWHM | shift^{β} | Stress^{π} | Anisotropy |
| Sample# | (%) | (cm⁻¹) | (cm⁻¹) | (GPa) | ratio^{γ} |
| A₁ | >98 | 5.6 | +2.7 | −1.53 | 1.12^{]} |
| A₂ | 94.9 | 7.9 | +0.5 | −0.28 | ~2.53 |
| A₃ | 82.4 | 9.3 | −2.3 | +1.30 | —^{δ} |
| A₄ | 75.4 | 21.4 | −3.3 | +1.87 | —^{δ} |
| B₂ | 83.6 | 11.5 | −2.6 | +1.47 | —^{δ} |
| B₃ | 92.5 | 9.3 | +1.3 | −0.73 | ~1.76 |
| B₄ | 97.1 | 8.8 | +2.1 | −1.19 | ~1.21 |
| B₅ | Similar to B₄ | 7.8 | +2.2 | −1.24 | ~1.21 |
| B₆ | Similar to B₄ | 6.6 | +2.3 | −1.30 | ~1.21 |

In connection with Table 1, the following is noted. The phase purity is calculated using the methodology explained in M. Malakoutian, M. A. Laurent, S. Chowdhury, Crystals 2019, 9, 1. In connection with the Raman shift column, higher re-nucleation rate applies tensile stress to the diamond layer and compensates for part of the compressive stress due to the CTE mismatch, and these Raman shift values were measured on diamond grown on GaN/SiC substrates. The anisotropy ratio in the far right column is diamond thickness divided by its grain size, and the blank entries indicated by ° are too large to be calculated. The residual stress, in the corresponding column, has been calculated using the method explained in M. Malakoutian, M. A. Laurent, S. Chowdhury, Crystals 2019, 9, 1. (among other references) and the Raman peak position shift.

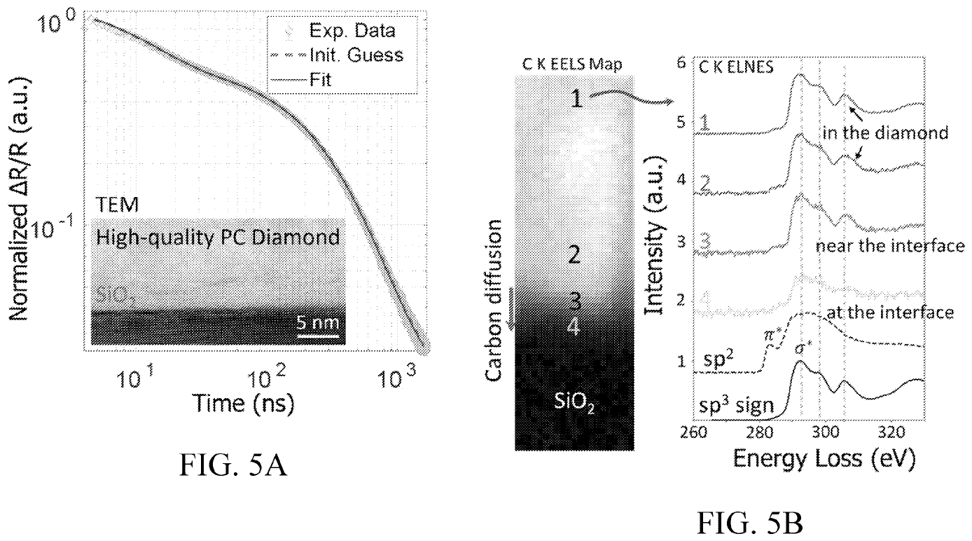

Discussion now turns to thermal and interface analysis also in connection with such more-detailed experimental example embodiments. In order to increase the heat transport coefficient of diamond heat spreader its TC must be as high as possible and the thermal boundary resistance (TBR) between diamond and the substrate needs to be as low as possible. In accordance with certain embodiments of the present disclosure as characterized in one or more examples above, low temperature diamond (sample #B₄ in FIG. 3C) has a grain size of 659 nm which in theory corresponds to an average TC between 300 and 400 W/m/K. Using the transient thermoreflectance (TTR) method and fitting the analytical model to the measured signal (see FIG. 5A), in connection with these experimental efforts TC and TBR of the diamond layer were measured. The 400° C.-grown diamond TC was measured in the range of 250 to 400 W/m/K with a mean value of ~300 W/m/K, consistent with the similar grain sizes grown at 700° C. The measured TC for the 400° C.-grown diamond is approximately 200% higher than the TC was reported (~110 W/m/K measured at 20° C.) for 300 nm-thick NCD diamond film which was grown at 450-500° C. This relatively high TC with only 798 nm of thickness is dedicated to the near-isotropic shape of the grains which decreases the phonon scattering rate in these grains and eventually enhances its thermal properties. Another advantage of this low temperature diamond is the high-quality nucleation at the interface which resulted in a TBR as low as 5 m²K/GW. This TBR is extremely close to 3.1 m²K/GW which was reported in one of the previous publications (names of the authors being common to names of the inventors of the present disclosure) for high temperature diamond grown at 700° C. FIG. 5B shows EELS mapping of carbon atoms with the change in the chemical bonding at the interface. An extremely sharp transition from SiO₂ to sp³ carbon (point 4→3) can be observed confirming a thin interfacial layer (less temperature profile discontinuity) and high-quality nucleation which supports the low TBR realized in connection with the efforts of the present disclosure.

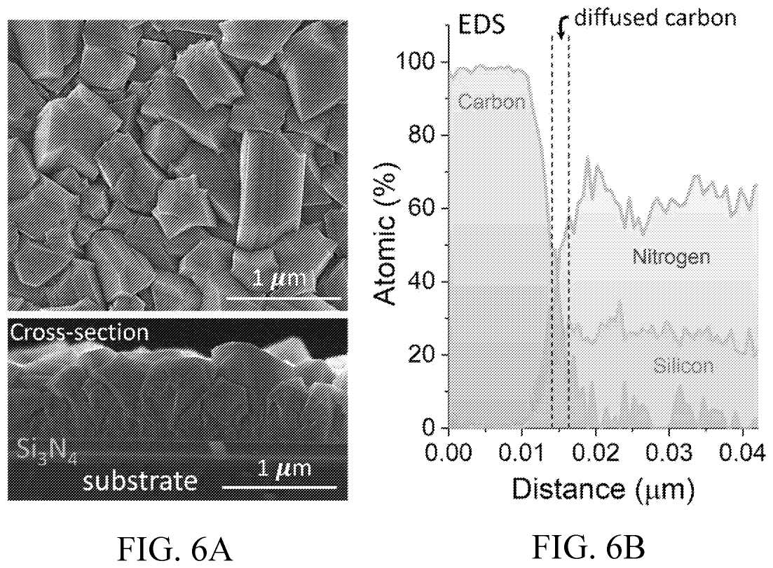

Such more-detailed experimental example embodiments also included diamond grown on Si₃N₄. In order to extend low temperature diamond application, optimized low temperature (400° C.) diamond growth technique, as discussed above, was utilized on Si₃N₄ to study the interface smoothness and diamond crystallite. As shown in FIG. 6A, the shape of the grains as well as the diamond nucleation is extremely (e.g., substantially) similar to SiO₂ substrates which emphasize the broadness of the seeding/nucleation method according to aspects of the present disclosure. With these efforts, a smooth interface with an average grain size between 500 and 700 nm has been realized. The interface between diamond and Si₃N₄ has been characterized using EDS as shown in FIG. 6B, thereby confirming a thin transition from carbon to Si₃N₄ which can enhance its thermal properties by reducing the thermal barrier thickness.

The above-described experiments involved various details as discussed below, and which details may be helpful in appreciating certain experimental embodiments and the related realizations. It is first noted that, prior to diamond growth, the samples were seeded by diamond particles using a mixed ultrasonication-polymer-assisted seeding technique. Then, PC diamond thin films were grown in an SDS 5000 series microwave plasma CVD reactor from Seki Diamond Systems. The reactant gases consisted of CH₄, the precursor to diamond, H₂, the reaction activator for C—C bonding by providing H-free reaction sites, and O₂ to minimize sp² carbon formation during low temperature growth. Multiple parameters were studied to optimize low temperature growth, which is summarized for each sample in Table 2. Plasma powers of 900-1300 W, chamber pressures of 20-40 Torr, temperatures of 300-500° C., CH₄ content of 0.5-5%, and O₂ content of 1-2% were employed.

Accordingly, Table 2 below shows growth parameters for different samples as were utilized in connection with these experimental efforts.

TABLE 2

| | Temp | Power | Pressure | Gas | |
|---|---|---|---|---|---|
| Sample# | (° C.) | (W) | (Torr) | System | Details |
| A₁ | 700 | 1600 | 60 | H₂/CH₄ | HT stage^{α} |
| A₂ | 500 | 1200 | 40 | H₂/CH₄ | HT stage |
| A₃ | 400 | 1300 | 45 | H₂/CH₄ | LT stage^{β} |
| A₄ | 300 | 950 | 30 | H₂/CH₄ | LT stage |
| B₁ | 400^{γ} | 1300 | 45 | H₂/O₂/CH₄ | Low CH₄% High |
| | | | | | O₂% |
| B₂ | 400 | 1300 | 45 | H₂/O₂/CH₄ | High CH₄% Low |
| | | | | | O₂% |
| B₃ | 400 | 1300 | 45 | H₂/O₂/CH₄ | 2-step technique |
| B₄ | 400 | 1300 | 45 | H₂/O₂/CH₄ | 3-steps technique |
| B₅ | 400 | 1300 | 45 | H₂/O₂/CH₄ | 3-steps, Medium |
| | | | | | CH₄% |
| B₆ | 400 | 1300 | 45 | H₂/O₂/CH₄ | Optimized |
| | | | | | nucleation |

Notes:
(^{α}denotes that HT stage refer to High temperature stage;
^{β}denotes that LT stage refers to Low Temperature stage; and
^{γ}denotes that all #B sample series were grown at 400° C. on LT stage).

After the diamond growth, the diamond layer's grain size and thickness were determined by scanning electron microscopy (FEI Nova NanoSEM 430). Scanning transmission electron microscopy (STEM), electron energy loss spectroscopy (EELS), and energy-dispersive spectroscopy (EDS) analysis (JEOL JEM 2100F-AC) were used for interface study and identification of the chemical bonding types at the interface. To assess the diamond crystalline quality, Raman spectroscopy measurements were made (HORIBA Scientific LabRAM HR Evolution spectrometer). The full-width-half-maximum (FWHM), relative areas under sp³ and sp² peaks, and red/blue shifts of Raman peaks were used to characterize the diamond quality, sp³ phase purity, and residual thermal stress, respectively. These properties were extracted from the Raman spectra using the method explained elsewhere. TTR was utilized for measuring the thermal properties of diamond including its TC and TBR with the substrate. Measurements were carried out on gold coated (as a transducer) diamond samples using a CW 532 nm probe laser along with a 355 nm passively Q-switched Nd: YAG pump laser with 1 ns pulse width, 10 kHz repetition rate, and 1/e² spot size of ~90 μm. Since multilayers of different materials are involved, the thermoreflectance data was fitted to the transient heat equation using the transmission-line-axis-symmetric model to extract both TBR and TC. The details of fixed and extracted parameters from the control samples without diamond are shown in Table 3 (showing fixed thermal properties used for TTR fitting. The thermal conductivities of layers other than diamond were extracted from control samples as indicated with *, and the symbol ^{α} denotes that two different substrates were used in connection with these experimental efforts and this study under the SiO₂ thin layer).

TABLE 3

| | TC | Heat Capacity | Density |
|---|---|---|---|
| | (W/m/K) | (J/kg/K) | (kg/m³) |
| Au | 315 | 129 | 19300 |
| TBR_{Cr-Diamond} | 0.3 (10 nm)* | — | — |
| Diamond | Fitted | 520 | 3510 |
| TBR_{Diamond-SiO2} | Fitted | — | — |
| SiO₂ | 1.18* | 600 | 2690 |
| Si/GaN | 105/150* | 700/470 | 2329/6150 |
| substrate^{α} | | | |

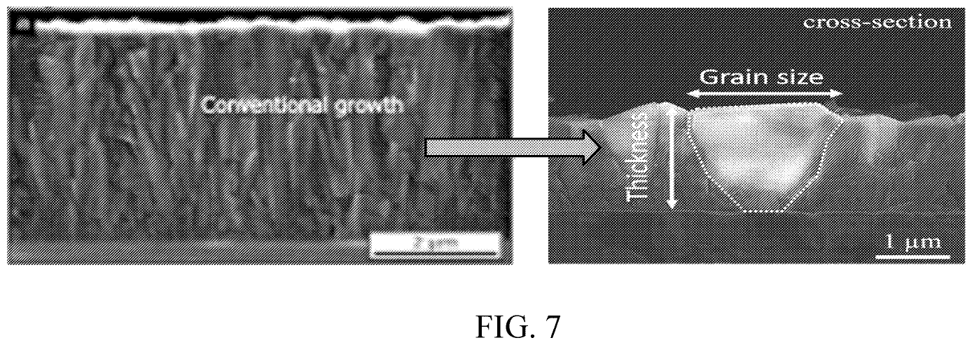

FIG. 7 is a set of images comparing more-conventional diamond grains having columnar structures with diamond grains having isotropic structures, with the right image in accordance with an experimental semiconductor device of the present disclosure wherein the diamond grains are grown under low temperature and with gas chemistry to etch sp² carbon (enhancing large-sized diamond grains via a dominance of sp³ carbon and mitigating stacking of diamond grains on top of one another). The more isotropic diamond grains as shown in the right image of FIG. 7 may represent the diamond across the TFP (or at least a portion or section of the TFP such as a first TFP section which is oriented in a direction along a first plane (e.g., substantially parallel to a surface over which FET contacts or an FET channel is formed) and may also represent the diamond across another part of the TFP (or at least a portion or section thereof such as a second TFP section as being along one side or all around the sides of the active region of the channel which is oriented in a direction along a plane that is orthogonal to or intersects with the first plane). For the first portion and the second portion, polycrystalline-diamond grains are more isotropic than columnar to minimize or reduce such grain boundaries between the polycrystalline-diamond grains, and/or to maximize in-plane thermal conductivity during operation of the circuit.

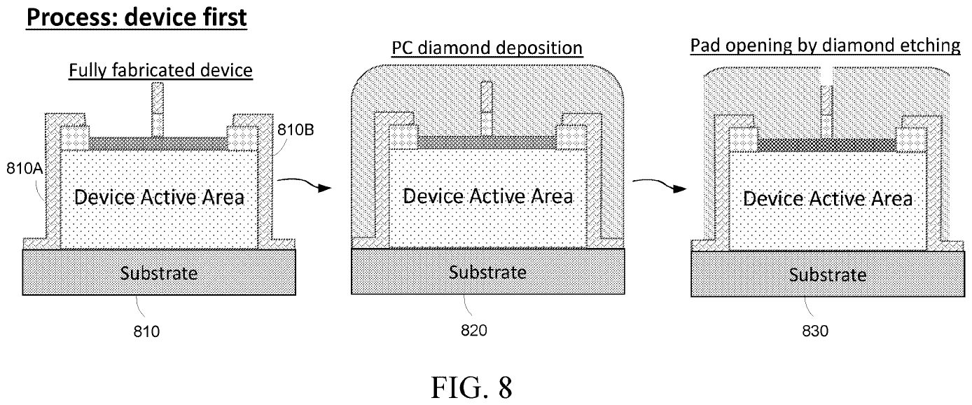

FIG. 8 is a generalized flow diagram according to specific exemplary experimental processes disclosed hereinabove. FIG. 8 shows relevant aspects of generalized manufacture device-first processing flow corresponding to a specific experimental example embodiment also in accordance with the present disclosure. In this example embodiment a FET is depicted with gate and source/drain contacts respectively over and to the left and right of the device active (channel region) area (and these portions of the FET may include and/or represent one or more doped layers configured to operate in a complementary manner as is known). It is appreciated that this example embodiment, in accordance with specific aspects of the present disclosure, may be adapted as either a 2D heat-spreading device with heat being transported via one plane of low-temperature-grown diamond or as a 3D heat-spreading device with heat being transported via multiple planes of low-temperature-grown diamond.

More specifically, the generalized flow diagram of FIG. 8 shows a 3D heat-spreading device-first process in three steps, step 810, step 820, and step 830. At step 810, a fully-fabricated device is shown as including all aspects except the PC-grown diamond layer as discussed above. At step 820, the same fully-fabricated device is shown with the low-temperature-grown (PC) diamond above and on the sides of the device active area which includes the channel (hot spot in the channel not illustrated).

Accordingly, steps 810 and 820 of FIG. 8 are illustrative of such examples wherein the low-temperature diamond is grown on a post-processed active device (e.g., a semiconductor wafer), growing diamond includes growing the diamond to conform to or be integrated as part of an active device, after construction of the active device and without undermining performance of the active device, and wherein the active device includes at least one of SiO₂, Si₃N₄, and a primarily Silicon-based device. It is noted, however, that such diamond may also be used with or grown on other (active) devices such as that based on GaN, Ga₂O₃, and/or InP. The diamond layer may be formed on any such layers of the semiconductor device (e.g., a substrate layer) to act as a diamond heat spreader for transporting heat, as characterized by a heat transport coefficient corresponding to a maximum measure of thermal conductivity and a minimized measure of thermal boundary resistance between the diamond layer and the adjacent layer.

At step 830 of FIG. 8, this fully-fabricated device is shown with access to the device's gate being provided by diamond etching. Access to the source and drain areas may be also provided by diamond etching from above or by way of conductive paths 810A and 810B being formed before step 820.

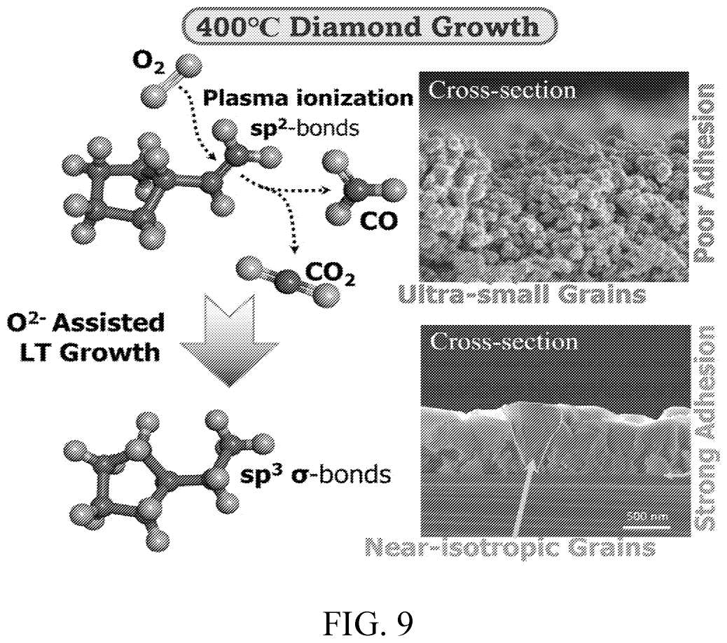

FIG. 9 is a set of depictions representing example aspects of gas chemistry used to realize various structures (via an exemplary diamond growth at about 400 degrees C.) discussed in connection with certain of the above-referenced illustrations (see e.g., the above-discussed FIGS. 2A, 2C (cross section) and FIG. 3C), also according to the present disclosure.

Many different types of processes, devices and applications may be advantaged by incorporating them with aspects as disclosed in the present disclosure, including the related examples in the identified references of the above-identified U.S. Provisional application. In connection with the present disclosure and/or the above-identified U.S. Provisional application, these references are identified with specificity by reference numerals shown inside brackets [#] including but not necessarily limited to those numbered starting with reference #1. Certain examples in this regard include Si-based devices which, as in many of the above contexts (where exemplary embodiments of the present disclosure discuss advantages in connection with Si-based circuits and/or Si-based components with a channel region), “Si-based” in these regards is used to characterize electrical current-controlling silicon-containing circuits and/or silicon-containing components wherein a silicon-containing component includes or is referred to as an active device (given its ability to electrically control electric charge flow and with the channel region characterizing where the electric charge flow occurs) as occurs in one or more of the following non-limiting examples: transistors (e.g., FET), silicon-on-insulator devices, silicon-controlled rectifiers, and silicon-containing active photonic devices, etc., where such circuit-related structures are used for functions including signal amplification, signal conversion, etc.

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices, and examples as described hereinabove may also be found in the drawings and appendix of the above-referenced Provisional Application.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected” or “operably coupled” (or “cooperatively configured” relative to each other to achieve the desired functionality. Specific examples in this regard include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

The skilled artisan would also recognize various terminology as used in the present disclosure. As examples, the Specification may describe and/or illustrates aspects useful for implementing the examples by way of various semiconductor materials/circuits which may be illustrated as or using terms such as layers, blocks, modules, device, system, unit, controller, steps, material, material layer and/or circuit layers and/or circuitry and/or other semiconductor- or circuit-related depictions (e.g., device in such contexts or “active device” refers to or includes a transistor and/or optical structure with a channel having mobility characteristics for conducting current). Also, in connection with such descriptions, the term “source” may refer to source and/or drain interchangeably in the case of a transistor structure. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. It is understood that examples of the present disclosure describes and/or illustrates aspects by way of reference to various processing steps, material, layers and/or other structural and functional aspects (including those in the U.S. Provisional application) and that such aspects may be used together with other elements to exemplify how certain embodiments may be carried out in the form or structures, steps of manufacture, functions, operations, activities, etc.

It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner. Further, unless otherwise noted, the use of the words “approximate,” “about,” “around,” “substantially,” etc., mean plus or minus ten percent.

Based upon the above discussion and illustrations, those skilled in the art will readily recognize that various modifications and changes may be made to the various embodiments without strictly following the exemplary embodiments and applications illustrated and described herein. For example, methods as exemplified in the Figures and/or description may involve steps carried out in various orders, with one or more aspects of the embodiments herein retained, or may involve fewer or more steps, unless specified differently above. Also, two or more steps may be performed concurrently or with partial concurrence, unless specified differently above.

1. A method comprising:
growing diamond, to produce a diamond layer, at a temperature of less than 600° C.; and
controlling growth of the diamond, during the diamond growth, by a gas chemistry that abates sp² carbon formation and enhances diamond grain sizes in both lateral and vertical directions in the diamond layer while mitigating new diamond grains from forming on top of each other.

2. (canceled)

3. (canceled)

4. The method of claim 1, wherein the diamond-growth chemistry uses O₂, or CO₂ to etch sp² carbon and enhance formation of sp³ carbon, wherein during operation of a semiconductor device including the diamond-growth chemistry, the method is to cause heat to be drawn from multiple sides of a hot spot in a channel region of the semiconductor device, without undermining performance of the semiconductor device during the operation.

5. The method of claim 1, wherein said growing diamond includes an initial nucleation stage and after the initial nucleation stage, the diamond-growth chemistry is introduced to remove sp² carbon, and wherein the low temperature is in a range from 600° C. to not less than about 200° C.

6. The method of claim 1, wherein said growing diamond includes a nucleation stage, the diamond-growth chemistry further includes a selected percentage or amount of diamond growth precursors (H₂: 85-100%, CH₄: 0-10%, 02:0-6%, CO₂: 0-10%) to optimize the nucleation stage, and the diamond layer is grown with diamond grains configured to provide a degree of phase purity of not less than about 90%.

7. The method of claim 6, wherein the percentage or amount of diamond growth precursor is selected by using a process that includes testing or sweeping for applying different percentages or amounts of the diamond growth precursors until an optimal percentage or amount of the CH₄, O₂, and CO₂ are found, and wherein the diamond layer is grown with diamond grains configured to provide optimal degrees of crystal quality and of phase purity similar to conventional high temperature diamonds.

8. The method of claim 1, wherein said growing diamond includes growing the diamond to conform to or be integrated as part of an active device, after construction of the active device and without undermining performance of the active device, and wherein the active device includes at least one of SiO₂, Si₃N₄, and a primarily Silicon-based device.

9. The method of claim 1, wherein the diamond layer is characterized by at least one of: an anisotropy ratio (diamond thickness/grain size), in terms of thickness to grain size, of not greater than 1.76 and not less than 1.21; an average thermal conductivity of not less than 300 W/m/K; and a thermal boundary resistance as low as 5 m²K/GW.

10. The method of claim 1, wherein the diamond layer is formed on an adjacent layer to act as a diamond heat spreader for transporting heat, as characterized by a heat transport coefficient corresponding to a maximum measure of thermal conductivity and a minimized measure of thermal boundary resistance between the diamond layer and the adjacent layer.

11. An apparatus comprising:
one or more semiconductor devices having a channel region associated with a hot spot which manifests during operation of the one or more semiconductor devices; and
diamond adjacent and sufficiently close to the channel region to, during operation of the one or more semiconductor devices, draw heat from multiple sides of the hot spot, wherein the diamond is a low-temperature growth diamond grown on a Si-based material after formation of the one or more semiconductor devices having a uniform diamond layer that is characterized by at least one of: a phase purity of greater than 90 percent, and diamond grains in uniform diamond layer being more isotropic than columnar, wherein Si-based active devices in the semiconductor devices are not damaged.

12. The apparatus of claim 11, further including a substrate layer to support the one or more semiconductor devices, wherein the diamond is configured and arranged with:
a first diamond layer adjacent the channel region and vertically separated from the substrate with at least a portion of the channel region located between the first diamond layer and the substrate layer; and a second diamond layer adjacent the channel region and elongated orthogonal to a plane along which at least a portion of the substrate layer is oriented, wherein during operation of the one or more semiconductor devices the first diamond layer is to draw heat away from the hot spot through the first diamond layer in a first spatial dimension, and the second diamond layer is to draw away heat from the hot spot through the first diamond layer in a second spatial dimension that is orthogonal to the first spatial dimension.

13. The apparatus of claim 12, further including a third diamond layer adjacent the channel region and elongated orthogonal to the plane along which said at least a portion of the substrate is oriented, wherein in operation of the one or more semiconductor devices the third diamond layer is to draw away heat from the hot spot through the first diamond layer in a third spatial dimension that is orthogonal to the first and second spatial dimensions.

14. (canceled)

15. The apparatus of claim 11, wherein the diamond has a thermal conductivity which is dependent on an average grain size associated with the diamond, and the diamond is characterized as at least one of the following: a low-temperature grown diamond manifesting an additive of oxygen to a gas mixture by adding one or more O₂ or CO₂ precursors, and a low-temperature grown diamond evidencing optimization of a nucleation stage during a growth stage or process of the diamond.

16. (canceled)

17. (canceled)

18. The apparatus of claim 11, wherein the diamond and the channel region are configured to manifest a temperature profile in the channel and which temperature profile, during operation of the one or more semiconductor devices, is characterized by an eventual reduction of a peak temperature and a flattening of the temperatures profile.

19. (canceled)

20. The apparatus of claim 11, wherein the one or more semiconductor devices is characterized as manifesting, due to dissipation of heat from the hot spot through the diamond, at least one of the following properties: an anisotropy ratio less than 1.3; a low thermal boundary resistance not exceeding 5 m²k/GW, and thermal conductivity of at least 300 W/mk.

21. (canceled)

22. (canceled)

23. The apparatus of claim 11, wherein the diamond is configured relative to the hot spot, to enhance dissipation of heat from the hot spot through the diamond by providing a minimized thermal boundary resistance (TBR) that is in a range from 1 to 15 m²K/GW.

24. The apparatus of claim 11, wherein the diamond is configured relative to the hot spot, to enhance dissipation of heat from the hot spot through the diamond by providing an enhanced thermal conductivity (TC) that is in a range from 100-1000 W/m/K.

25. The apparatus of claim 11, wherein the diamond is characterized as being low-temperature-grown diamond characterized having a phase purity, wherein low-temperature grown diamond refers to diamond grown under 600 degrees C.

26. The apparatus of claim 11, wherein the one or more semiconductor devices includes a transistor, having at least one of GaN, Ga₂O₃, and InP, that is operable at high switching speeds that are at least partially attributable to said at least one of GaN, Ga₂O₃, and InP in the transistor causing the one or more semiconductor devices to generate heat at the hot spot.

27. A method comprising:
growing low-temperature diamond under 600 degrees C., on a wafer including one or more Si-based semiconductor devices having a channel region, adjacent and sufficiently close to the channel region to cause, during operation of the one or more semiconductor devices, heat to be drawn from multiple sides of a hot spot in the channel region, without undermining performance during operation of the one or more semiconductor devices.

28. The method of claim 27, wherein the configuration or location of the diamond enhances a thermal resistance characteristic for material adjacent the channel region, which thermal resistance characteristic corresponds to a high temperature peak in a temperature profile of the channel that is eventually lowered and flattened during the operation, and said growing low-temperature diamond includes growing the diamond to conform to or be integrated as part of an active device, after construction of the active device and without undermining performance of the active device during the operation.

29. (canceled)
